(19) United States
(12) Patent Application Publication
(10) Pub. No.: US 2026/0121613 A1
(43) Pub. Date: Apr. 30, 2026

(54) ROBUST CONNECTION METAL STRUCTURES FOR SAW DEVICE APPLICATION

(71) Applicant: Qorvo US, Inc., Greensboro, NC (US)

(72) Inventor: Myung Gyu Kang, Greensboro, NC (US)

(21) Appl. No.: 18/928,966

(22) Filed: Oct. 28, 2024

(51) Int. Cl. H03H 9/145; H03H 3/08; H03H 9/02; H03H 9/25; H03H 9/64

(52) U.S. Cl. CPC H03H 9/14541; H03H 3/08; H03H 9/02637; H03H 9/25; H03H 9/6483

(57) ABSTRACT

The present disclosure relates to a surface acoustic wave (SAW) device with robust metal structures, which at least provide electrically low resistance and mechanically strong connections between different inter digital transducers (IDTs) within the SAW device. Each metal structure includes a metal base section that is formed from a same metal layer as corresponding IDTs, and a metal stack over the metal base section. The metal stack includes a bottom adhesive layer over the metal base section, a bottom conductive layer over the bottom adhesive layer, an intermediate adhesive layer over the bottom conductive layer, a top conductive layer over the intermediate adhesive layer, and a top adhesive layer over the top conductive layer. The bottom and top conductive layers have a higher electrical conductivity than each adhesive layer, while each adhesive layer has a stronger adhesion strength than the bottom and top conductive layers.

### FIELD OF THE DISCLOSURE

The present disclosure relates to a surface acoustic wave (SAW) device, and particularly to a SAW device with robust metal structures for internal and/or external connections. The metal structures are configured to provide electrically low resistance and mechanically strong connections between different inter digital transducers (IDTs) of one or more SAW resonators within the SAW device, and/or from the IDTs of certain SAW resonators within the SAW device to external circuitry.

### BACKGROUND

Acoustic wave devices are widely used in modern electronics. At a high level, acoustic wave devices include a piezoelectric material in contact with one or more electrodes. Piezoelectric materials acquire a charge when compressed, twisted, or distorted, and similarly compress, twist, or distort when a charge is applied to them. Accordingly, when an alternating electrical signal is applied to the one or more electrodes in contact with the piezoelectric material, a corresponding mechanical signal (i.e., an oscillation or vibration) is transduced therein. The mechanical signal transduced in the piezoelectric material exhibits a frequency dependence on the alternating electrical signal based on the characteristics of the one or more electrodes on the piezoelectric material, the properties of the piezoelectric material, and other factors such as the shape of the acoustic wave device and other structures provided on the device. Acoustic wave devices leverage this frequency dependence to provide one or more functions.

Surface acoustic wave (SAW) devices, such as SAW filters, are increasingly used in the transmission and reception of radio frequency (RF) signals for communication. For example, the SAW filters are commonly used in second generation (2G), third generation (3G), and fourth generation (4G) wireless receiver front ends, duplexers, and receive filters. The widespread use of the SAW filters is due, at least in part, to the fact that the SAW filters exhibit low insertion loss with good rejection, can achieve broad bandwidths, and are a small fraction of the size of traditional cavity and ceramic filters. As the use of the SAW filters in modern RF communication systems and mobile devices increases, there is a need for SAW filters with high reliability and high yield.

### SUMMARY

The present disclosure relates to a surface acoustic wave (SAW) device with robust metal structures, which provide electrically low resistance and mechanically strong connections between different inter digital transducers (IDTs) of one or more SAW resonators within the SAW device, and/or from the IDTs of certain SAW resonators within the SAW device to external circuitry. The disclosed SAW device includes a piezoelectric layer, a number of reflective structures, a number of IDTs, and metal structures configured to provide connections among the IDTs. Herein, the reflective structures, the IDTs, and the metal structures reside over the piezoelectric layer, and each of the IDTs is arranged between a corresponding pair of the reflective structures. Each of the metal structures includes a metal base section, which resides over the piezoelectric layer and is directly in contact with corresponding ones of the IDTs, and a metal stack over the metal base section. The metal stack includes a bottom adhesive layer directly over the metal base section, a bottom conductive layer directly over the bottom adhesive layer, an intermediate adhesive layer directly over the bottom conductive layer, a top conductive layer directly over the intermediate adhesive layer, and a top adhesive layer directly over the top conductive layer. In addition, each of the bottom conductive layer and the top conductive layer has a higher electrical conductivity than the bottom adhesive layer, the intermediate adhesive layer, and the top adhesive layer, while each of the bottom adhesive layer, the intermediate adhesive layer, and the top adhesive layer has a stronger adhesion strength than the bottom conductive layer and the top conductive layer.

In one embodiment of the SAW device, the metal structures are further configured to provide connections between certain ones of the IDTs to ground.

In one embodiment of the SAW device, the metal structures are further configured to provide a connection between at least one of the IDTs to an input port of the SAW device and provide a connection between at least one of the IDTs to an output port of the SAW device.

In one embodiment of the SAW device, the bottom adhesive layer, the intermediate adhesive layer, and the top adhesive layer are formed of Titanium (Ti). The bottom adhesive layer has a thickness between 500 Å and 3000 Å, the intermediate adhesive layer has a thickness between 100 Å and 500 Å, and the top adhesive layer has a thickness between 500 Å and 3000 Å.

In one embodiment of the SAW device, the intermediate adhesive layer has a thickness of about 200 Å.

In one embodiment of the SAW device, the bottom conductive layer and the top conductive layer are formed of a same material.

In one embodiment of the SAW device, the bottom conductive layer and the top conductive layer are formed of different materials.

In one embodiment of the SAW device, the bottom conductive layer is formed of aluminum (Al) or copper (Cu), and the top conductive layer is formed of Al or Cu.

In one embodiment of the SAW device, the bottom adhesive layer, the bottom conductive layer, the intermediate adhesive layer, the top conductive layer, and the top adhesive layer are formed of Ti, Al, Ti, Al, and Ti, respectively. The bottom adhesive layer has a thickness between 500 Å and 3000 Å, the bottom conductive layer has a thickness between 1 μm and 2.5 μm, the intermediate adhesive layer has a thickness between 100 Å and 500 Å, the top conductive layer has a thickness between 1 μm and 2.5 μm, and the top adhesive layer has a thickness between 500 Å and 3000 Å.

In one embodiment of the SAW device, the bottom conductive layer and the top conductive layer have a same thickness.

In one embodiment of the SAW device, the bottom conductive layer and the top conductive layer have different thicknesses.

In one embodiment of the SAW device, a combined thickness of the bottom conductive layer and the top conductive layer is between 2 μm and 4.5 μm, or between 3 μm and 5 μm.

According to one embodiment, the SAW device further includes a substrate. The substrate, the piezoelectric layer, the reflective structures, and the IDTs constitute a number of SAW resonators, each of which is composed of a portion of the substrate, a portion of the piezoelectric layer, a pair of the reflective structures, and one or more of the IDTs located between the pair of the reflective structures. The metal structures are at least configured to provide connections between the SAW resonators, between at least one of the SAW resonators to an input port of the SAW device, between at least one of the SAW resonators to an output port of the SAW device, and between certain ones of the SAW resonators to ground.

In one embodiment of the SAW device, at least one of the SAW resonators includes more than one of the IDTs between the corresponding pair of the reflective structures, and the metal structures are further configured to provide connections between the more than one of the IDTs within the at least one of the SAW resonators.

In one embodiment of the SAW device, the IDTs and the metal base section of each of the metal structures are formed from a same metal layer.

According to one embodiment, the SAW device further includes a patterned dielectric layer over the piezoelectric layer. Herein, the patterned dielectric layer covers each of the reflective structures and each of the IDTs without covering any of the metal structures, and covers portions of the piezoelectric layer, which are not covered by the reflective structures, the IDTs, and the metal structures.

According to one embodiment, a system includes radio-frequency (RF) input circuitry, RF output circuitry and filter circuitry that has at least one SAW device connected between the RF input circuitry and the RF output circuitry. Herein, the at least one SAW device includes a piezoelectric layer, a number of reflective structures, a number of IDTs, and metal structures configured to provide connections among the IDTs. The reflective structures, the IDTs, and the metal structures reside over the piezoelectric layer, and each of the IDTs is arranged between a corresponding pair of the reflective structures. Each of the metal structures includes a metal base section, which resides over the piezoelectric layer and is directly in contact with corresponding ones of the IDTs, and a metal stack over the metal base section. The metal stack includes a bottom adhesive layer directly over the metal base section, a bottom conductive layer directly over the bottom adhesive layer, an intermediate adhesive layer directly over the bottom conductive layer, a top conductive layer directly over the intermediate adhesive layer, and a top adhesive layer directly over the top conductive layer. In addition, each of the bottom conductive layer and the top conductive layer has a higher electrical conductivity than the bottom adhesive layer, the intermediate adhesive layer, and the top adhesive layer, while each of the bottom adhesive layer, the intermediate adhesive layer, and the top adhesive layer has a stronger adhesion strength than the bottom conductive layer and the top conductive layer.

According to one embodiment, a method of fabricating a SAW device with robust metal structures, which provide electrically low resistance and mechanically strong connections among IDTs within the SAW device, starts with forming a piezoelectric layer. Next, a number of reflective structures, the IDTs, and a number of metal base sections are formed over the piezoelectric layer. Each of the IDTs is arranged between a corresponding pair of the reflective structures, and the IDTs and the metal base sections are formed from a same metal layer. Each of the metal base sections is directly in contact with corresponding ones of the IDTs. After the metal base sections are prepared, a metal stack is deposited to each of the metal base sections to form a metal structure, which provides connections among the IDTs. Herein, the metal stack includes a bottom adhesive layer directly over a corresponding one of the metal base sections, a bottom conductive layer directly over the bottom adhesive layer, an intermediate adhesive layer directly over the bottom conductive layer, a top conductive layer directly over the intermediate adhesive layer, and a top adhesive layer directly over the top conductive layer. Each of the bottom conductive layer and the top conductive layer has a higher electrical conductivity than the bottom adhesive layer, the intermediate adhesive layer, and the top adhesive layer, while each of the bottom adhesive layer, the intermediate adhesive layer, and the top adhesive layer has a stronger adhesion strength than the bottom conductive layer and the top conductive layer.

In one embodiment of the method, depositing the metal stack includes depositing the bottom adhesive layer directly over the corresponding one of the metal base sections, depositing the bottom conductive layer directly over the bottom adhesive layer, depositing the intermediate adhesive layer directly over the bottom conductive layer, depositing the top conductive layer directly over the intermediate adhesive layer, and depositing the top adhesive layer directly over the top conductive layer.

In one embodiment of the method, the bottom adhesive layer, the intermediate adhesive layer, and the top adhesive layer are formed of Ti. The bottom conductive layer is formed of Al or Cu, and the top conductive layer is formed of Al or Cu.

In one embodiment of the method, each of the bottom conductive layer and the top conductive layer has a thickness between 1 μm and 2.5 μm and is formed from one pocket resource.

In one embodiment of the method, the bottom adhesive layer has a thickness between 500 Å and 3000 Å, the intermediate adhesive layer has a thickness between 100 Å and 500 Å, and the top adhesive layer has a thickness between 500 Å and 3000 Å. The bottom adhesive layer and the intermediate adhesive layer are deposited at a rate between 1 Å/second and 2 Å/second.

According to one embodiment, the method further includes forming a patterned dielectric layer over the piezoelectric layer before depositing the metal stack to each of the metal base sections. Herein, the patterned dielectric layer covers each of the reflective structures and each of the IDTs but leaves each of the metal base sections exposed. In addition, the patterned dielectric layer covers portions of the piezoelectric layer that are not covered by the reflective structures, the IDTs, and the metal base sections.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 provides a perspective view illustration of a representative surface acoustic wave (SAW) resonator with a single inter digital transducer (IDT).

FIGS. 2A-2B show a SAW device with multiple SAW resonators.

FIG. 3 shows an alternative SAW device with one or more SAW resonators, each of which includes more than one IDT.

FIG. 4 shows a cross-sectional view of a traditional implementation of one electric connection route between two IDTs.

FIGS. 5A-5C show a SAW device that utilizes a metal stack to reduce electrical resistance of connection routes among/within SAW resonators of the SAW device.

FIG. 6 illustrates a metal structure including a conventional metal stack, which is used to implement internal and/or external connection routes within a SAW device.

FIG. 7 illustrates a metal structure including a robust metal stack, which is used to implement the internal and/or external connection routes within a SAW device according to some embodiments of the present disclosure.

FIG. 8 illustrates a flowchart of an exemplary method of providing a SAW device with a robust metal stack according to some embodiments of the present disclosure.

FIG. 9 illustrates a block diagram of an example system that includes at least one SAW device with the robust metal stack shown in FIG. 7.

FIG. 10 illustrates a block diagram of an exemplary communication device that includes at least one SAW device with the robust metal stack shown in FIG. 7.

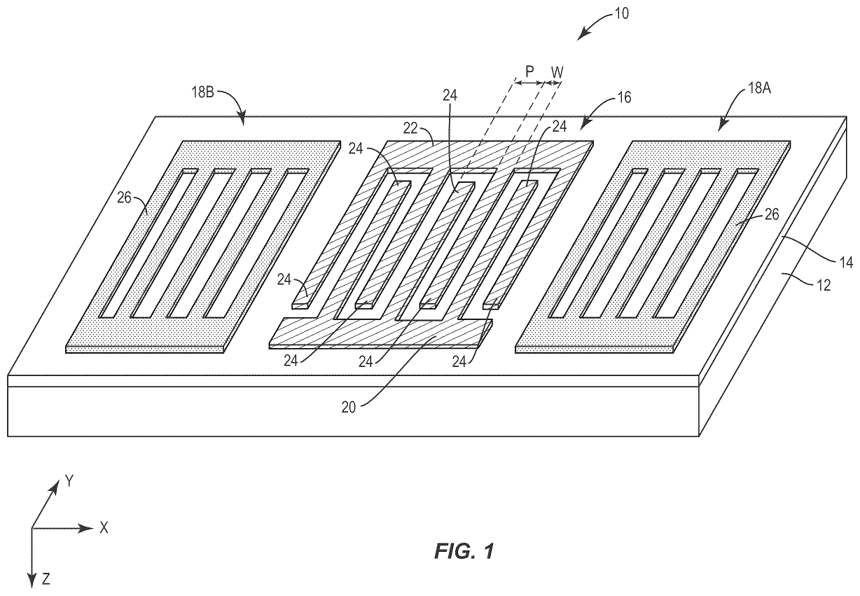

It will be understood that for clarity of illustration, FIGS. 1-10 may not be drawn to scale.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to a surface acoustic wave (SAW) device, and particularly to a SAW device with a robust metal stack for internal and/or external connections. Herein, the metal stack is configured to connect different inter digital transducers (IDTs) of one or more SAW resonators within the SAW device, and/or connect the IDTs of certain SAW resonators within the SAW device to external circuitry.

Before describing particular embodiments of the present disclosure further, a general discussion of SAW devices is provided. FIG. 1 provides a perspective view illustration of a representative SAW resonator 10. The SAW resonator 10 includes a substrate 12, a piezoelectric layer 14 on the substrate 12, an IDT 16 on a surface of the piezoelectric layer 14 opposite the substrate 12, and two reflective structures 18A and 18B on the surface of the piezoelectric layer 14 placed at opposite sides of the IDT 16.

The IDT 16 includes a first electrode 20 and a second electrode 22, each of which may include one or more electrode fingers 24 that are interleaved with one another as shown. The first electrode 20 and the second electrode 22 may also be referred to as comb electrodes. For the purpose of this illustration, the first electrode 20 of the IDT 16 includes three electrode fingers 24, and the second electrode 22 of the IDT 16 includes four electrode fingers 24. In different applications, the first/second electrode 20/22 may have fewer or more electrode fingers. A number of the electrode fingers 24 within the first electrode 20 and a number of the electrode fingers 24 within the second electrode 22 may be different or the same (not shown). A lateral distance between adjacent electrode fingers 24 of the first electrode 20 and the second electrode 22 defines an electrode pitch P of the IDT 16. The electrode pitch P may at least partially define a center frequency wavelength λ of the SAW resonator 10, where the center frequency is the primary frequency of mechanical waves generated in the piezoelectric layer 14 by the IDT 16. A finger width W of the adjacent electrode fingers 24 over the electrode pitch P may define a metallization ratio, or duty factor, of the IDT 16, which may dictate certain operating characteristics of the SAW resonator 10.

In operation, an alternating electrical input signal provided at the first electrode 20 is transduced into a mechanical signal in the piezoelectric layer 14, resulting in one or more acoustic waves therein. In the case of the SAW resonator 10, the resulting acoustic waves are predominately surface acoustic waves. As discussed above, due to the electrode pitch P and the metallization ratio of the IDT 16, the characteristics of the material of the piezoelectric layer 14, and other factors, the magnitude and frequency of the acoustic waves transduced in the piezoelectric layer 14 are dependent on the frequency of the alternating electrical input signal. This frequency dependence is often described in terms of changes in the impedance and/or a phase shift between the first electrode 20 and the second electrode 22 with respect to the frequency of the alternating electrical input signal. An alternating electrical potential between the two electrodes 20 and 22 creates an electrical field in the piezoelectric material which generates acoustic waves. The acoustic waves travel at the surface and eventually are transferred back into an electrical signal between the electrodes 20 and 22. The two reflective structures 18A and 18B reflect the acoustic waves in the piezoelectric layer 14 back towards the IDT 16 to confine the acoustic waves in the area surrounding the IDT 16. Each reflective structure 18A or 18B may include one or more reflective fingers 26 (only two reflective fingers are labeled with a reference number for clarity). A number of the reflective fingers 26 within the reflective structure 18A and a number of the reflective fingers 26 within the reflective structure 18B may be different (not shown) or the same.

The substrate 12 may be formed of various materials including glass, sapphire, quartz, silicon (Si), or gallium arsenide (GaAs) among others, with Si being a common choice. The piezoelectric layer 14 may be formed of any suitable piezoelectric material(s), such as lithium tantalate (LT), or lithium niobate (LiNbO₃), but is not limited thereto. In certain embodiments, the piezoelectric layer 14 is thick enough or rigid enough to function as a piezoelectric substrate. Accordingly, the substrate 12 in FIG. 1 may be omitted. Those skilled in the art will appreciate that the principles of the present disclosure may apply to other materials for the substrate 12 and the piezoelectric layer 14. The IDT 16 and the two reflective structures 18A and 18B may include aluminum (Al). While not shown to avoid obscuring the drawings, additional passivation layers, frequency trimming layers, or any other layers may be provided over all or a portion of the exposed surface of the piezoelectric layer 14, the IDT 16, and the two reflective structures 18A and 18B. Further, one or more layers may be provided between the substrate 12 and the piezoelectric layer 14 in some embodiments.

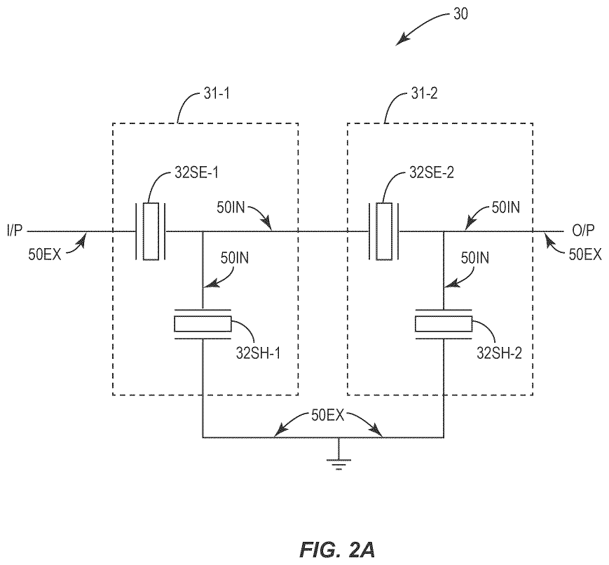

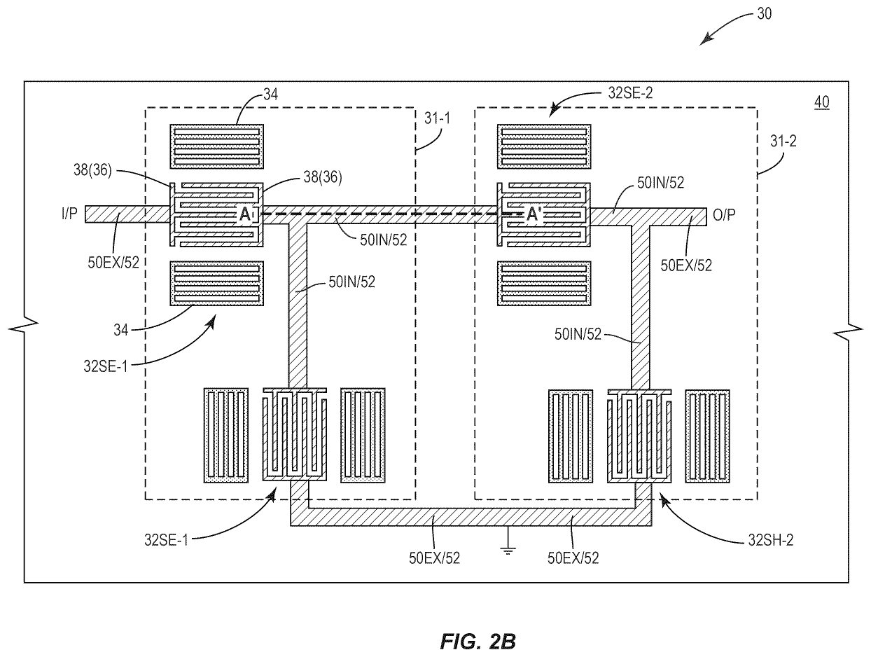

SAW resonators are widely used in filter networks that operate at high frequencies and require high Q values. A SAW device 30 having multiple SAW resonators 32 implements a filter configuration, as illustrated in FIGS. 2A and 2B. FIG. 2A shows a schematic of the SAW device 30, while FIG. 2B shows a layout implementation of the SAW device 30. For the purpose of this illustration, the SAW device 30 is a ladder filter with two filtering stages 31 (e.g., a first filtering stage 31-1 and a second filtering stage 31-2), each of which includes a series SAW resonator 32SE (e.g., a first series SAW resonator 32SE-1 and a second series SAW resonator 32SE-2) and a shunt SAW resonator 32SH (e.g., a first shunt SAW resonator 32SH-1 and a second shunt SAW resonator 32SH-2, respectively). The series SAW resonators 32SE are coupled in series between an input port (I/P) and an outport (O/P), while each shunt SAW resonator 32SH is arranged between a corresponding series resonator 32SE and ground.

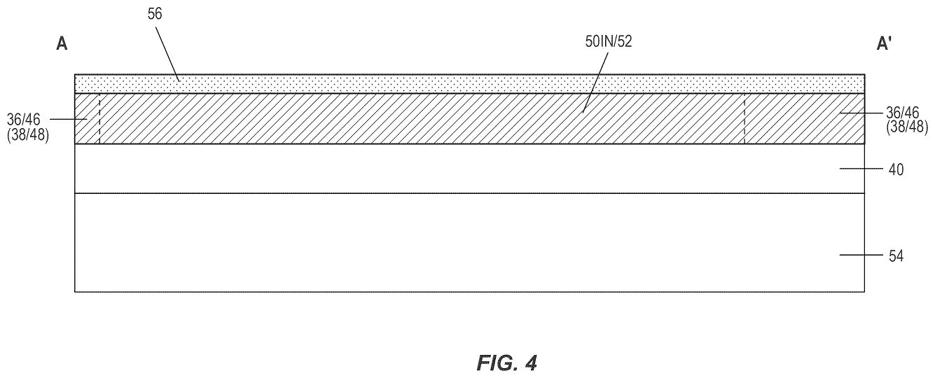

Herein, each SAW resonator 32 is similar to the SAW resonator 10 described above and includes a pair of reflective structures 34 (similar to the reflective structures 18A and 18B of the SAW resonator 10) and an IDT 36 with corresponding electrodes 38 (similar to the electrodes 20 and 22 of the IDT 16 in the SAW resonator 10) between the pair of reflective structures 34 (only two reflective structures, one IDT, and two electrodes of the first series SAW resonator 32SE-1 are labeled with reference numbers for clarity). The series resonators 32SE and the shunt resonators 32SH within the SAW device 30 may share a same piezoelectric layer 40 and a substrate (not shown in FIG. 2B, see a substrate 54 shown in FIG. 4). In other words, the reflective structures 34 and the IDT 36 of each SAW resonator 32 reside on the same common piezoelectric layer 40, and the common piezoelectric layer 40 is formed over the common substrate (not shown in FIG. 2B, see the substrate 54 shown in FIG. 4). In different applications, the SAW device 30 may include more than two filtering stages 31, may achieve the filtering function in different configurations, or may achieve other acoustic functions (like an acoustic duplexer). Each SAW resonator 32 may also be a temperature compensated (TC) SAW resonator, a Guided SAW resonator, or the like.

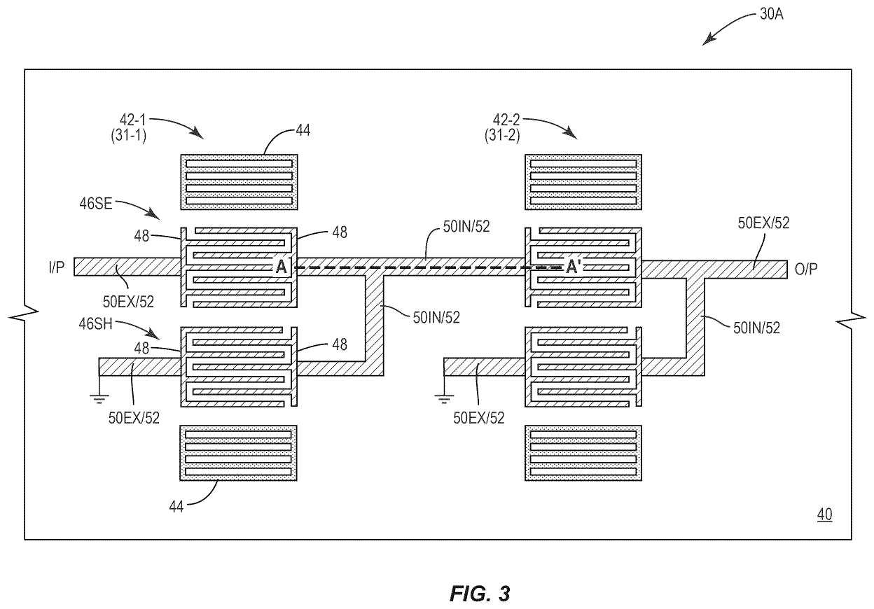

In the above description, each SAW resonator 32 within the SAW device 30 only includes the single IDT 36 between the pair of reflective structures 34. To reduce the size of one SAW device and maintain the power and linearity performances, the SAW device may also be implemented by ladder-type SAW resonators, which include series and shunt IDTs sharing a same pair of reflective structures. FIG. 3 illustrates a SAW device 30A with ladder-type SAW resonators 42, which achieves the same functionality of the SAW device 30 as shown in FIGS. 2A and 2B.

For the purpose of this illustration, the SAW device 30A includes two ladder-type SAW resonators 42 (e.g., a first ladder-type SAW resonator 42-1 and a second ladder-type SAW resonator 42-2), each of which operates a same function as a corresponding filtering stage 31 shown in FIG. 2A and replaces the series and shunt SAW resonators 32SE and 32SH in the corresponding filtering stage 31. Herein, each ladder-type SAW resonator 42 includes a pair of reflective structures 44 (similar to the reflective structures 34 of the SAW resonator 32), a series IDT 46SE, and a shunt IDT 46SH. The series IDT 46SE and the shunt IDT 46SH within each ladder-type SAW resonator 42 includes two electrodes 48 (similar to the electrodes 38 of the SAW resonator 32) used for internal and external connections. The series IDTs 46SE in both of the ladder-type SAW resonators 42 are coupled in series between an I/P and an O/P, while each shunt IDTs 46SH is arranged between a corresponding series IDT 46SE and ground. In addition, the ladder-type SAW resonators 42 may share the same piezoelectric layer 40 and the substrate (not shown in FIG. 3, see the substrate 54 shown in FIG. 4). In other words, the reflective structures 44, the series IDT 46SE, and the shunt IDT 46SH of each ladder-type SAW resonator 42 reside on the same common piezoelectric layer 40 and the common substrate (not shown in FIG. 3, see the substrate 54 shown in FIG. 4). In different applications, the SAW device 30A may include more than two ladder-type SAW resonators 42 and the SAW device 30A and/or the ladder-type SAW resonators 42 may be implemented in different configurations (as described and illustrated in U.S. Pat. No. 11,070,194 B2 titled “LADDER-TYPE SURFACE ACOUSTIC WAVE DEVICE”).

As shown in FIGS. 2A and 2B, internal connection routes 50IN are configured to provide connections among the series and shunt resonators 32 (i.e., configured to provide connections among the IDT 36 of different series/shunt resonators 32), while external connection routes 50EX are configured to provide connections from certain series/shunt resonators 32 to the input port I/P, the output port O/P, and ground, respectively (i.e., configured to provide connections from the IDT 36 of the certain series/shunt resonators 32 to the input port I/P, the output port O/P, and ground, respectively). Similarly, as shown in FIG. 3, the internal connection routes 50IN are configured to provide connections between different ladder-type SAW resonators 42 (i.e., configured to provide connections between the series IDTs 46SE of the different ladder-type SAW resonators 42) and configured to provide connections between different IDTs 46 within one ladder-type SAW resonator 42 (i.e., configured to provide connections between the series IDT 46SE and the shunt IDT 46SH within one ladder-type SAW resonator 42). The external connection routes 50EX are configured to provide connections from the ladder-type SAW resonators 42 to the input port I/P, the output port O/P, and ground, respectively (i.e., configured to provide connections from the series IDTs 46SE to the input port I/P and the output port O/P, respectively, and provide connections from each shunt IDT 46SH to ground).

In traditional SAW device fabrications, the internal/external connection routes 50 used to provide connections between different IDTs 36/46 (i.e., different electrodes 38/48) of the SAW resonators 32/42 are typically implemented by metal base sections 52, which might be formed at a same time as the IDTs 36/46 with a same material, such as Al (more details are described in the following paragraphs). FIG. 4 shows a cross-sectional view of one metal base section 52, which implements one electronic connection route 50 between two IDTs 36/46 along a dashed line A-A′ shown in FIG. 2B and FIG. 3. Herein, the piezoelectric layer 40 is formed over the substrate 54, and the IDTs 36/46 and the metal base section 52 are formed over the piezoelectric layer 40. It is clear that the metal base section 52 extends continuously and directly from one IDT 36/46 to another IDT 36/46. In some applications, there is a dielectric layer 56 covering each IDT 36/46, each metal base section 52, each reflective structure 34/44 (not shown), and exposed portions of a top surface of the piezoelectric layer 40 (not shown). For clarity and simplicity, the dielectric layer 56 is not illustrated in FIGS. 2B and 3.

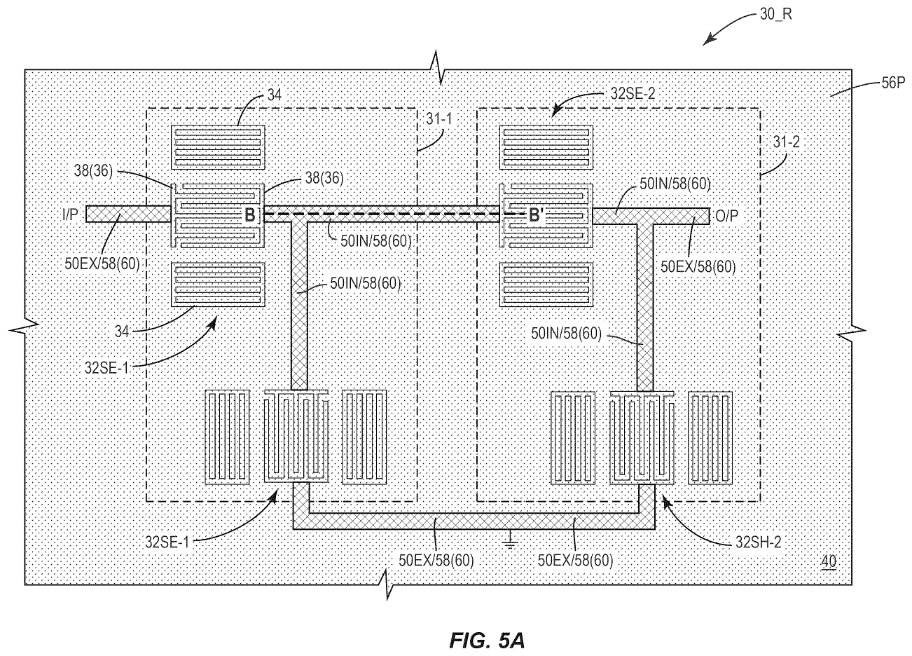

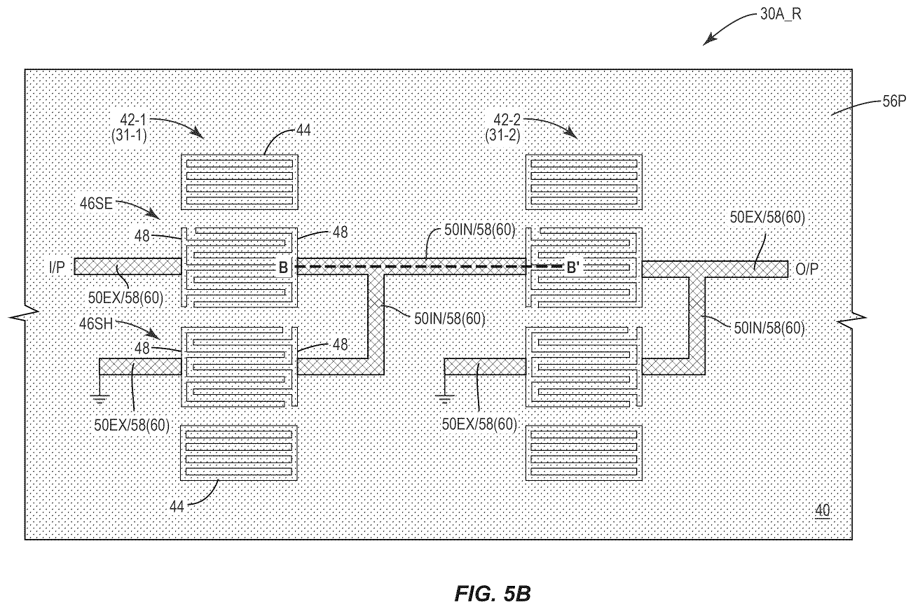

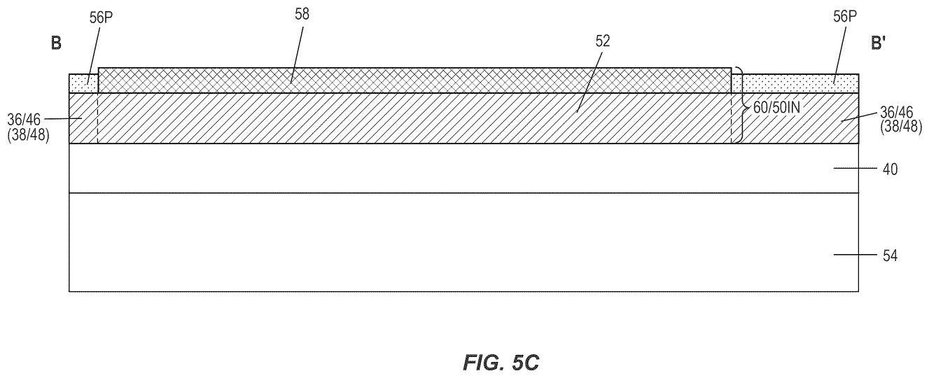

However, the metal base section 52, which is formed of the same material as the IDTs 36/46, may provide poor electrical connections (e.g., the internal connection routes 50IN and the external connection routes 50EX) due to a relatively large electrical resistance. In order to reduce the electrical resistance of the electrical connections among the IDTs 36/46, a metal stack 58 is typically deposited over each metal base section 52 to form a relatively thick metal structure 60, which possesses a significantly reduced resistance. FIG. 5A shows a SAW device 30_R that is similar to the SAW device 30 shown in FIG. 2B and further includes the metal stacks 58 for reduced electrical connections. FIG. 5B shows a SAW device 30A_R that is similar to the SAW device 30 shown in FIG. 3 and further includes the metal stacks 58, and FIG. 5C shows a cross-sectional view of one metal structure 60, which implements one internal connection route 50IN between two IDTs 36/46 along a dashed line B-B′ shown in FIG. 5A and FIG. 5B.

The SAW device 30_R illustrated in FIG. 5A includes the SAW resonators 32 over the piezoelectric layer 40 (as described above), while the SAW device 30A_R illustrated in FIG. 5B includes the ladder-type SAW resonators 42 over the piezoelectric layer 40 (as described above). In the SAW device 30_R/30A_R, instead of covering every component on the top surface of the piezoelectric layer 40, a patterned dielectric layer 56P covers each IDT 36/46, each reflective structure 34/44, and the exposed portions of the top surface of the piezoelectric layer 40 but leaves each metal base section 52 exposed. One metal stack 58 is directly deposited on a corresponding metal base section 52 to provide one metal structure 60. As such, each internal/external connection route 50 is implemented by a corresponding metal structure 60. Compared to the metal base sections 52 alone, the metal mass of the metal structures 60 is significantly increased, which results in a substantial reduction in electrical resistance of the internal/external connection route 50 connected to the SAW resonators 32/42. In some applications, the metal stacks 58 of certain metal structures 60 may extend over portions of the patterned dielectric layer 56P, which surround the metal base sections 52 (not shown).

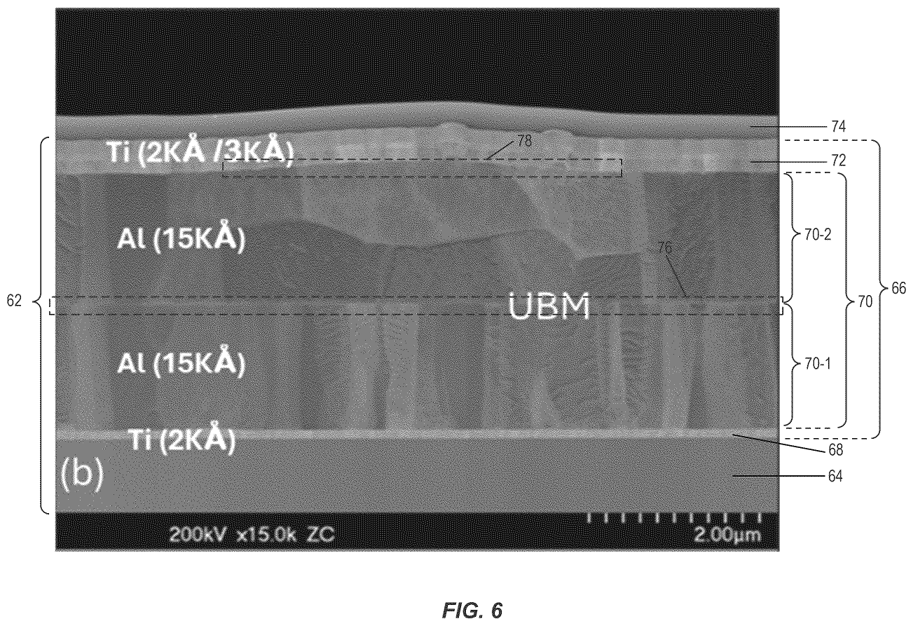

In different applications, various structural configurations can be applied to the metal stacks 58 as well as the metal structures 60 used to achieve low-resistance internal/external connection routes 50. FIG. 6 shows an experimental cross-sectional view of a portion of a conventional metal structure 62 used to implement one internal/external connection route within one SAW device (e.g., to implement one internal/external connection route 50 within the SAW device 30_R/30A_R shown in FIGS. 5A and 5B). The conventional metal structure 62 includes a metal base section 64 (similar to the metal base section 52) and a metal stack 66 directly over the metal base section 64. Herein, the metal base section 64 is formed from a same metal layer (e.g., Al) as corresponding/connecting IDTs (as described above). The metal stack 66 includes a bottom Titanium (Ti) layer 68 directly formed over the metal base section 64, an aluminum (Al) section 70 over the bottom Ti layer 68, and a top Ti layer 72 over the Al section 70. In some applications, there might be one or more extra layers 74 formed over the conventional metal structure 62.

In order to achieve minimum resistive loss for low insertion loss in the SAW device, the Al section 70 sandwiched between the bottom and top Ti layers 68 and 72 desires more than 3 μm. Due to the limitation of deposition tool/technology, the thick Al section 70 (e.g., over 3 μm) is typically deposited from two pocket sources, which creates an interface 76 within the Al section 70. In other words, a first Al layer 70-1 of the Al section 70 is deposited from one pocket source, while a second Al layer 70-2 of the Al section 70 is deposited from another pocket source, such that the interface 76 is formed between the first Al layer 70-1 and the second Al layer 70-2. The interface 76 is the weakest point within the Al section 70 and is very sensitive to external stress applied to the SAW device. In a non-limiting example, when the SAW device experiences a relatively large temperature change, which causes a relatively large external stress to the SAW device, there will be a potential deformation risk of the SAW device that may result in separation of the first Al layer 70-1 and the second Al layer 70-2 at the interface 76.

In addition, another issue that may arise with the thick Al section 70 is the formation of Al hillocks 78 during the deposition of the thick Al section 70. Typically, when the deposited Al section 70 is thicker than 2.5 μm, the Al hillocks 78 may appear. Although the Al hillocks 78 are shown to have no impact to filtering device performance and reliability, the Al hillocks 78 of the Al section 70 may still be caught during automatic optical inspection (AOI) since the Al hillocks 78 can lead to an uneven device surface of the SAW device and the AOI cannot differentiate the Al hillocks 78 from other fabrication defects. As such, the AOI may provide a low device yield, which is inaccurate and undesired.

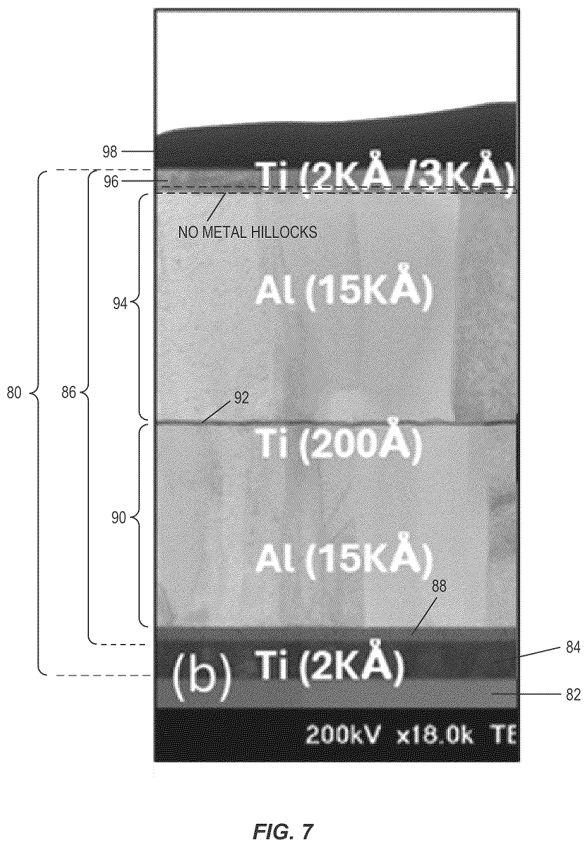

FIG. 7 illustrates an experimental cross-sectional view of a portion of an improved metal structure 80 used to implement one internal/external connection route within a SAW device (e.g., to implement one internal/external connection route 50 within the SAW device 30_R/30A_R shown in FIGS. 5A and 5B) according to some embodiments of the present disclosure. The improved metal structure 80 resides on a piezoelectric layer 82 (similar to the piezoelectric layer 40 described above) and includes a metal base section 84 (similar to the metal base section 52) and a robust metal stack 86 directly over the metal base section 84.

Herein, the piezoelectric layer 82 might be formed of any suitable piezoelectric material(s), such as LT, LiNbO₃, quartz, aluminum nitride (AlN), scandium-doped aluminum nitride (ScAlN), magnesium hydrofluoric acid aluminum nitride (MgHfAlN), magnesium zirconium aluminum nitride (MgZrAlN), and magnesium titanium aluminum nitride (MgTiAlN), but is not limited thereto. The metal base section 84 is formed from a same metal layer as corresponding/connecting IDTs (as described above, not shown). The metal base section 84 and the corresponding IDTs may be formed of one or more conductive materials, such as Al, copper (Cu), platinum (Pt) and/or the like (e.g., Al over Cu, Al0.5%Cu, Al, AlCu over Cu over AlCu, Cu, or Al over Ti over Pt). In some applications, there might be an adhesive layer (not shown, e.g., Ti layer) vertically between the piezoelectric layer 82 and the metal base section 84 of the improved metal structure 80, and there might be another adhesive layer (not shown, e.g., Ti layer) above the metal base section 84 to accommodate the robust metal stack 86 deposited to the metal base section 84.

In addition to providing electrically low resistance, the robust metal stack 86 is also mechanically strong enough to avoid/reduce the risk of metal layer separation. Furthermore, the formation of the robust metal stack 86 may not create metal hillocks that would affect the device yields. Herein, the robust metal stack 86 includes a bottom adhesive layer 88, a bottom conductive layer 90, an intermediate adhesive layer 92, a top conductive layer 94, and a top adhesive layer 96, where the bottom conductive layer 90 and the top conductive layer 94 constitute the majority of the robust metal stack 86. In detail, the bottom adhesive layer 88 fully covers and is directly over the metal base section 84, and the bottom conductive layer 90 fully covers and is directly over the bottom adhesive layer 88. To achieve a low electrical resistance, the bottom conductive layer 90 of the robust metal stack 86 is required to be formed of a material with a high electrical conductivity, such as Al or Cu, which, however, does not have a strong adhesive strength. As such, the bottom adhesive layer 88 is herein provided to adhere/connect the bottom conductive layer 90 to the metal base section 84. Ti is a possible material for the bottom adhesive layer 88 due to its strong adhesive strength. The thickness of the bottom conductive layer 90 is between 1 μm and 2.5 μm (e.g., about 1.5 μm, within 10% offset from 1.5 μm), which can be deposited as a one-piece layer without hillocks by a single pocket source. The thickness of the bottom adhesive layer 88 is between 500 Å and 3000 Å (e.g., about 2000 Å, within 10% offset from 2000 Å), which provides sufficient adhesion without adding significant electrical resistance.

The top conductive layer 94 is formed over the bottom conductive layer 90 via the intermediate adhesive layer 92. Similar to the bottom conductive layer 90, the top conductive layer 94 is required to be formed of a material with a high electrical conductivity, such as Al or Cu, to achieve a low electrical resistance. The intermediate adhesive layer 92 is configured to provide robust adhesion/connection between the top conductive layer 94 and the bottom conductive layer 90 and may be formed of Ti. The thickness of the top conductive layer 94 is between 1 μm and 2.5 μm (e.g., about 1.5 μm, within 10% offset from 1.5 μm), which can be deposited as a one-piece layer without hillocks by a single pocket source. The thickness of the intermediate adhesive layer 92 is between 100 Å and 300 Å (e.g., about 200 Å, within 10% offset from 200 Å) or between 100 Å and 500 Å, which provides sufficient adhesion between the bottom and top conductive layers 90 and 94 without adding significant electrical resistance.

Note that the bottom conductive layer 90 and the top conductive layer 94 may be formed of a same material or different materials (e.g., Al and Al, Al and Cu, Cu and Al, or Cu and Cu for the bottom conductive layer 90 and the top conductive layer 94, respectively). Each of the bottom conductive layer 90 and the top conductive layer 94 has a higher electrical conductivity than the bottom, intermediate, and top adhesive layers 88, 92, and 96, while each of the bottom, intermediate, and top adhesive layers 88, 92, and 96 has a stronger adhesion strength than the bottom and top conductive layers 90 and 96. In addition, the bottom conductive layer 90 and the top conductive layer 94 may have a same thickness or different thicknesses, as long as the thickness of each of the bottom conductive layer 90 and the top conductive layer 94 is not thicker than 2.5 μm and a combined thickness of the bottom conductive layer 90 and the top conductive layer 94 is greater than 2 μm (e.g., between 2 μm and 4.5 μm, or between 3 μm and 5 μm). The top adhesive layer 96 is formed directly over the top conductive layer 94 and may be formed of Ti with a thickness between 500 Å and 3000 Å (e.g., about 2000 Å, within 10% offset from 2000 Å). In some applications, there might be one or more extra layers 98 formed over the improved metal structure 80, and the top adhesive layer 96 may provide adhesion to the one or more extra layers 98.

With the bottom adhesive layer 88, the robust metal stack 86 can be firmly connected/bonded to the metal base section 84. With the intermediate adhesive layer 92, the bottom and top conductive layers 90 and 94 can be firmly bonded to each other, and the robust metal stack 86 remains as one robust/solid structure without cracking under external pressure. It is also clearly shown that utilizing the intermediate adhesive layer 92 to connect the relatively thin bottom conductive layer 90 (e.g., thinner than 2.5 μm) and the relatively thin top conductive layer 94 (e.g., thinner than 2.5 μm) instead of forming a thick conduct section with an interface will reduce/avoid metal hillocks and increase interface strength in the robust metal stack 86. For non-limiting examples, the robust metal stack 86 (in a sequence order of the bottom adhesive layer 88, the bottom conductive layer 90, the intermediate adhesive layer 92, a top conductive layer 94, and the top adhesive layer 96) may have a Ti—Al—Ti—Al—Ti configuration, a Ti—Cu—Ti—Al—Ti configuration, a Ti—Al—Ti—Cu—Ti configuration, or a Ti—Cu—Ti—Cu—Ti configuration.

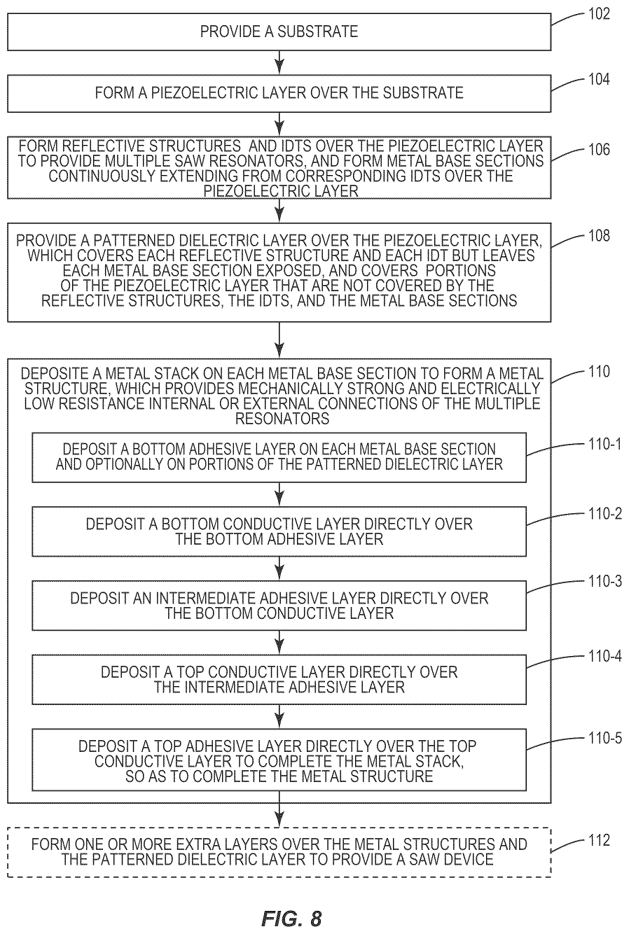

FIG. 8 illustrates a flowchart of an exemplary method of providing a SAW device (e.g., the SAW device 30R/30A_R shown in FIGS. 5A and 5B) utilizing the improved metal structure 80 to implement electrically low resistance and mechanically strong connection routes between different IDTs within the SAW device (e.g., implement electrically low resistance and mechanically strong internal and external connection routes 50 between different IDTs 36/46 in the SAW device 30R/30A_R) according to some embodiments of the present disclosure. Although the process steps are illustrated in a series, the process steps are not necessarily order dependent. Some steps may be taken in a different order than that presented. Further, processes within the scope of this disclosure may include fewer or more steps than those illustrated in FIG. 8. Initially, a substrate (e.g., the substrate 54 shown in FIG. 5C) is provided (step 102), which may be formed of various materials including glass, sapphire, quartz, Si, or GaAs among others, with Si being a common choice. A piezoelectric layer (e.g., the piezoelectric layer 40 shown in FIG. 5C or the piezoelectric layer 82 shown in FIG. 7) is then formed over the substrate (step 104). The piezoelectric layer might be formed of one or more suitable piezoelectric materials, such as LT, LiNbO₃, quartz, AlN, ScAlN, MgHfAlN, MgZrAlN, and/or MgTiAlN, but is not limited thereto. Next, a number of IDTs and corresponding pairs of reflective structures (e.g., the IDTs 36/46 and the reflective structures 34/44 shown in FIGS. 5A-5C) are formed over the piezoelectric layer to provide multiple SAW resonators (e.g., the SAW resonators 32/42 shown in FIGS. 5A-5B), and multiple metal base sections, which continuously extend from corresponding IDTs, respectively (e.g., the base sections 52 shown in FIG. 5C), are formed over the piezoelectric layer (step 106). Herein, the IDTs and the metal base sections are formed at a same time and formed from a same metal layer/material(s).

After the SAW resonators and the metal base sections are prepared, a patterned dielectric layer (e.g., the patterned dielectric layer 56P shown in FIGS. 5A-5C) is provided over the piezoelectric layer (step 108). The patterned dielectric layer covers each reflective structure and each IDT but leaves each metal base section exposed. In addition, the patterned dielectric layer covers portions of the piezoelectric layer that are not covered by the reflective structures, the IDTs, and the metal base sections.

Next, a robust metal stack (e.g., the robust metal stack 86 as shown in FIG. 7) is deposited on each metal base section to form a metal structure (e.g., the improved metal structure 80 as shown in FIG. 7), which provides mechanically strong and electrically low resistance internal/external connections of the SAW resonators (step 110). The metal stack may be formed by an electron beam evaporation process. Forming the metal stack starts with depositing a bottom adhesive layer (e.g., the bottom adhesive layer 88 as shown in FIG. 7) directly over a corresponding metal base section (sub-step 110-1). Optionally, the bottom adhesive layer may also be deposited on portions of the patterned dielectric layer, which are surrounding the corresponding metal base section. In order to achieve sufficient uniformity of the bottom adhesive layer and reduce metal hillocks in the final product, the bottom adhesive layer is deposited in a slow rate (e.g., as low as 1 Å/second, between 1 Å/second and 2 Å/second). The bottom adhesive layer might be formed of Ti with a thickness between 500 Å and 3000 Å (e.g., about 2000 Å, within 10% offset from 2000 Å).

Next, a bottom conductive layer (e.g., the bottom conductive layer 90 as shown in FIG. 7) is deposited directly over the bottom adhesive layer (sub-step 110-2). The bottom conductive layer is deposited from one pocket source; thus, no interface exists within the bottom conductive layer. The bottom conductive layer is formed of a material with a high electrical conductivity, such as Al or Cu, with a thickness between 1 μm and 2.5 μm (e.g., about 1.5 μm, within 10% offset from 1.5 μm). The relatively thin thickness of the bottom conductive layer reduces/avoids the formation of metal hillocks. The bottom adhesive layer is configured to adhere/connect the bottom conductive layer to the IDTs and the piezoelectric layer.

An intermediate adhesive layer (e.g., the intermediate adhesive layer 92 as shown in FIG. 7) is then deposited directly over the bottom conductive layer (sub-step 110-3). The intermediate adhesive layer might be formed of Ti with a thickness between 100 Å and 300 Å (e.g., about 200 Å, within 10% offset from 200 Å) or between 100 Å and 500 Å, which provides sufficient adhesion strength without adding significant electrical resistance and prohibits/reduces Al hillock formation. In order to achieve sufficient uniformity of the thin intermediate adhesive layer and reduce metal hillocks in the final product, the intermediate adhesive layer is also desired to be deposited in a slow rate (e.g., as low as 1 Å/second, between 1 Å/second and 2 Å/second).

A top conductive layer (e.g., the top conductive layer 94 as shown in FIG. 7) is deposited directly over the intermediate adhesive layer (sub-step 110-4). The intermediate adhesive layer is configured to provide strong adhesion between the top conductive layer and the bottom conductive layer. Similar to the bottom conductive layer, the top conductive layer is also deposited from one pocket source, thus, no interface exists within the top conductive layer. The top conductive layer is formed of a material with a high electrical conductivity, such as Al or Cu, to achieve a low electrical resistance. A thickness of the top conductive layer is relatively thin, between 1 μm and 2.5 μm (e.g., about 1.5 μm, within 10% offset from 1.5 μm), which reduces/avoids the formation of metal hillocks. Note that the bottom conductive layer and the top conductive layer may be formed of a same material or different materials (e.g., Al and Al, Al and Cu, Cu and Al, or Cu and Cu for the bottom conductive layer and the top conductive layer, respectively). In addition, the bottom conductive layer and the top conductive layer may have a same thickness or different thicknesses, as long as the thickness of each of the bottom conductive layer and the top conductive layer is not thicker than 2.5 μm and a combined thickness of the bottom conductive layer and the top conductive layer is greater than 2 μm (e.g., between 2 μm and 4.5 μm, or between 3 μm and 5 μm).

A top adhesive layer (e.g., the top adhesive layer 96 as shown in FIG. 7) is deposited directly over the top conductive layer to complete the metal stack, so as to complete the metal structure (sub-step 110-5). The top adhesive layer is configured to accommodate extra layers/structures (above the metal stack) adhered to the metal stack. The top adhesive layer might be formed of Ti with a thickness between 500 Å and 3000 Å (e.g., about 2000 Å, within 10% offset from 2000 Å). Since the top adhesive layer is the very top layer of the metal stack and is very thin, the top adhesive layer has little effect on the formation of the metal hillocks. As such, the top adhesive layer is not required to be deposited in a slow rate and might be deposited in a faster rate than the bottom and intermediate adhesive layers (e.g., as fast as 8 Å/second). Lastly, after the metal structure is completed, one or more extra layers are optionally formed over the metal structure and the patterned dielectric layer to provide the SAW device (step 112).

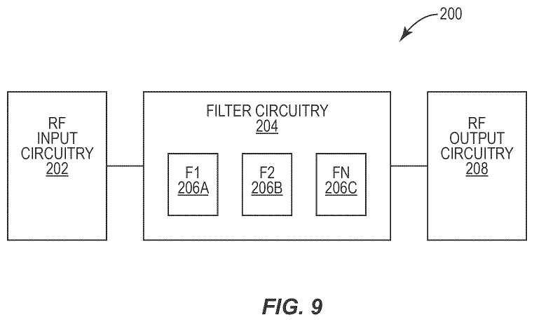

FIG. 9 illustrates a block diagram of an example system 200 that includes at least one SAW device with the improved metal structure 80 as illustrated in FIG. 7. The system 200 includes radio frequency (RF) input circuitry 202 connected to filter circuitry 204. In certain embodiments, the RF input circuitry 202 includes a transceiver.

For the purpose of this illustration, the filter circuitry 204 includes three filters 206A, 206B, and 206C. Herein, one or more of the filters 206A, 206B, and 206C may be the SAW device 30. Within the filter 206A, the filter 206B, and/or the filter 206C, or between the filters 206A, 206B, and 206C, the metal structure 80 might be used for electrical connection. In different applications, the filter circuitry 204 may include more or fewer filters. In one embodiment, each of the filters 206A, 206B, and 206C may be a lowpass filter, a high-pass filter, a notch filter, or a bandpass filter, and the filters 206A, 206B, and 206C may be connected in a cascaded arrangement. The filter types that are included in the filter circuitry 204 may be based at least on the rejection requirements of the system 200.

The filter circuitry 204 is connected to an RF output circuitry 208. In certain embodiments, the RF output circuitry 208 includes an antenna. The RF input circuitry 202 and/or the RF output circuitry 208 may include additional or different components in other embodiments.

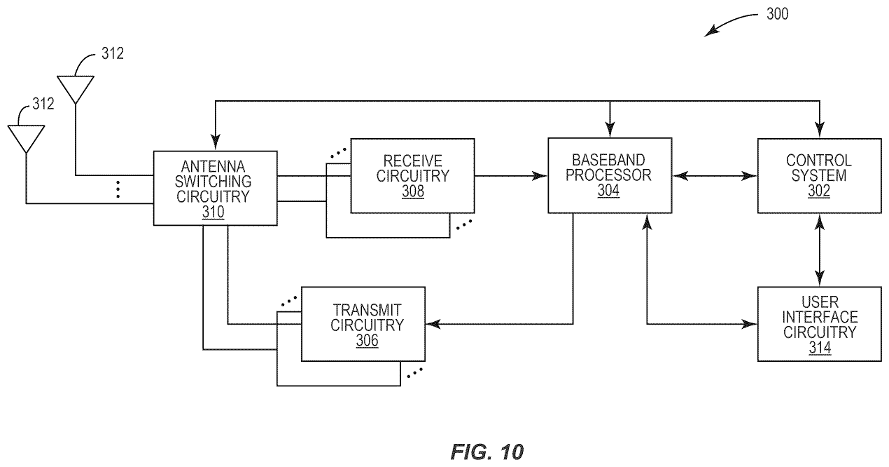

FIG. 10 illustrates a block diagram of an exemplary communication device 300 including at least one SAW device (e.g., a SAW filter) with the improved metal structure 80 as illustrated in FIG. 7. Herein, the communication device 300 can be any type of communication devices, such as mobile terminals, smart watches, tablets, computers, navigation devices, access points, base stations (e.g., eNB or gNB), and any other type of wireless communication devices that support wireless communications, such as cellular, wireless local area network (WLAN), Bluetooth, Ultra-wideband (UWB), and near field communications. The communication device 300 will generally include a control system 302, a baseband processor 304, transmit circuitry 306, receive circuitry 308, antenna switching circuitry 310, multiple antennas 312, and user interface circuitry 314. In a non-limiting example, the control system 302 can be a field-programmable gate array (FPGA) or an application-specific integrated circuit (ASIC), as an example. In this regard, the control system 302 can include at least a microprocessor(s), an embedded memory circuit(s), and a communication bus interface(s). The receive circuitry 308 receives radio frequency signals via the antennas 312 and through the antenna switching circuitry 310 from one or more base stations. A low noise amplifier and a filter (e.g., the SAW filter as described above) of the receive circuitry 308 cooperate to amplify and remove broadband interference from the received signal for processing. Down conversion and digitization circuitry (not shown) will then down convert the filtered, received signal to an intermediate or baseband frequency signal, which is then digitized into one or more digital streams using an analog-to-digital converter(s) (ADC).

The baseband processor 304 processes the digitized received signal to extract the information or data bits conveyed in the received signal. This processing typically comprises demodulation, decoding, and error correction operations, as will be discussed in greater detail below. The baseband processor 304 is generally implemented in one or more digital signal processors (DSPs) and ASICs.

For transmission, the baseband processor 304 receives digitized data, which may represent voice, data, or control information, from the control system 302, which it encodes for transmission. The encoded data is output to the transmit circuitry 306, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission and deliver the modulated carrier signal to the antennas 312 through the antenna switching circuitry 310 to the antennas 312. The multiple antennas 312 and the replicated transmit and receive circuitries 306, 308 may provide spatial diversity. Modulation and processing details will be understood by those skilled in the art. In some embodiments, the at least one SAW device 30 (e.g., a SAW filter) implemented with the metal structure 80 may be provided in any one or more of the circuitries in the communication device 300, such as the transmit circuitry 306, the receive circuitry 308, and/or the antenna switching circuitry 310.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A surface acoustic wave (SAW) device, comprising:
a piezoelectric layer;
a plurality of reflective structures;
a plurality of interdigital transducers (IDTs), wherein the plurality of reflective structures and the plurality of IDTs reside over the piezoelectric layer, and each of the plurality of IDTs is arranged between a corresponding pair of the plurality of reflective structures; and
metal structures configured to provide connections among the plurality of IDTs, wherein:
each of the metal structures includes a metal base section, which resides over the piezoelectric layer and is directly in contact with corresponding ones of the plurality of IDTs, and a metal stack over the metal base section;
the metal stack includes a bottom adhesive layer directly over the metal base section, a bottom conductive layer directly over the bottom adhesive layer, an intermediate adhesive layer directly over the bottom conductive layer, a top conductive layer directly over the intermediate adhesive layer, and a top adhesive layer directly over the top conductive layer; and
each of the bottom conductive layer and the top conductive layer has a higher electrical conductivity than the bottom adhesive layer, the intermediate adhesive layer, and the top adhesive layer, while each of the bottom adhesive layer, the intermediate adhesive layer, and the top adhesive layer has a stronger adhesion strength than the bottom conductive layer and the top conductive layer.

2. The SAW device of claim 1 wherein the metal structures are further configured to provide connections between certain ones of the plurality of IDTs to ground.

3. The SAW device of claim 1 wherein the metal structures are further configured to provide a connection between at least one of the plurality of IDTs to an input port of the SAW device and provide a connection between at least one of the plurality of IDTs to an output port of the SAW device.

4. The SAW device of claim 1 wherein:
the bottom adhesive layer, the intermediate adhesive layer, and the top adhesive layer are formed of Titanium (Ti);
the bottom adhesive layer has a thickness between 500 Å and 3000 Å;
the intermediate adhesive layer has a thickness between 100 Å and 500 Å; and
the top adhesive layer has a thickness between 500 Å and 3000 Å.

5. The SAW device of claim 4 wherein the intermediate adhesive layer has a thickness of about 200 Å.

6. The SAW device of claim 1 wherein the bottom conductive layer and the top conductive layer are formed of a same material.

7. The SAW device of claim 1 wherein the bottom conductive layer and the top conductive layer are formed of different materials.

8. The SAW device of claim 1 wherein:
the bottom conductive layer is formed of aluminum (Al) or copper (Cu); and
the top conductive layer is formed of Al or Cu.

9. The SAW device of claim 1 wherein:
the bottom adhesive layer, the bottom conductive layer, the intermediate adhesive layer, the top conductive layer, and the top adhesive layer are formed of Ti, Al, Ti, Al, and Ti, respectively;
the bottom adhesive layer has a thickness between 500 Å and 3000 Å;
the bottom conductive layer has a thickness between 1 μm and 2.5 μm;
the intermediate adhesive layer has a thickness between 100 Å and 500 Å;
the top conductive layer has a thickness between 1 μm and 2.5 μm; and
the top adhesive layer has a thickness between 500 Å and 3000 Å.

10. The SAW device of claim 1 wherein the bottom conductive layer and the top conductive layer have a same thickness.

11. The SAW device of claim 1 wherein the bottom conductive layer and the top conductive layer have different thicknesses.

12. The SAW device of claim 1 wherein a combined thickness of the bottom conductive layer and the top conductive layer is between 2 μm and 4.5 μm.

13. The SAW device of claim 12 wherein a combined thickness of the bottom conductive layer and the top conductive layer is between 3 μm and 5 μm.

14. The SAW device of claim 1 further comprising a substrate, wherein:
the substrate, the piezoelectric layer, the plurality of reflective structures, and the plurality of IDTs constitute a plurality of SAW resonators, each of which is composed of a portion of the substrate, a portion of the piezoelectric layer, a pair of the plurality of reflective structures, and one or more of the plurality of IDTs located between the pair of the plurality of reflective structures; and
the metal structures are at least configured to provide connections between the plurality of SAW resonators, between at least one of the plurality of SAW resonators to an input port of the SAW device, between at least one of the plurality of SAW resonators to an output port of the SAW device, and between certain ones of the plurality of SAW resonators to ground.

15. The SAW device of claim 14 wherein at least one of the plurality of SAW resonators includes more than one of the plurality of IDTs between the corresponding pair of the plurality of reflective structures, and the metal structures are further configured to provide connections between the more than one of the plurality of IDTs within the at least one of the plurality of SAW resonators.

16. The SAW device of claim 1 wherein the plurality of IDTs and the metal base section of each of the metal structures are formed from a same metal layer.

17. The SAW device of claim 1 further comprising a patterned dielectric layer over the piezoelectric layer, wherein the patterned dielectric layer covers each of the plurality of reflective structures and each of the plurality of IDTs without covering any of the metal structures, and covers portions of the piezoelectric layer, which are not covered by the plurality of reflective structures, the plurality of IDTs, and the metal structures.

18. A system comprising:
radio-frequency (RF) input circuitry;
RF output circuitry; and
filter circuitry, which includes at least one SAW device, connected between the RF input circuitry and the RF output circuitry, wherein the at least one SAW device comprises:
a piezoelectric layer;
a plurality of reflective structures;
a plurality of interdigital transducers (IDTs), wherein the plurality of reflective structures and the plurality of IDTs resides over the piezoelectric layer, and each of the plurality of IDTs is arranged between a corresponding pair of the plurality of reflective structures; and
metal structures configured to provide connections among the plurality of IDTs, wherein:
each of the metal structures includes a metal base section, which resides over the piezoelectric layer and is directly in contact with corresponding ones of the plurality of IDTs, and a metal stack over the metal base section;
the metal stack includes a bottom adhesive layer directly over the metal base section, a bottom conductive layer directly over the bottom adhesive layer, an intermediate adhesive layer directly over the bottom conductive layer, a top conductive layer directly over the intermediate adhesive layer, and a top adhesive layer directly over the top conductive layer; and
each of the bottom conductive layer and the top conductive layer has a higher electrical conductivity than the bottom adhesive layer, the intermediate adhesive layer, and the top adhesive layer, while each of the bottom adhesive layer, the intermediate adhesive layer, and the top adhesive layer has a stronger adhesion strength than the bottom conductive layer and the top conductive layer.

19. A method of fabricating a surface acoustic wave (SAW) device, comprising:
forming a piezoelectric layer;
forming a plurality of reflective structures, a plurality of interdigital transducers (IDTs), and a plurality of metal base sections over the piezoelectric layer, wherein:
each of the plurality of IDTs is arranged between a corresponding pair of the plurality of reflective structures;
the plurality of IDTs and the plurality of metal base sections are formed from a same metal layer; and
each of the plurality of metal base sections is directly in contact with corresponding ones of the plurality of IDTs;
depositing a metal stack to each of the plurality of metal base sections to form a metal structure, which provides connections among the plurality of IDTs, wherein:
the metal stack includes a bottom adhesive layer directly over a corresponding one of the plurality of metal base sections, a bottom conductive layer directly over the bottom adhesive layer, an intermediate adhesive layer directly over the bottom conductive layer, a top conductive layer directly over the intermediate adhesive layer, and a top adhesive layer directly over the top conductive layer; and
each of the bottom conductive layer and the top conductive layer has a higher electrical conductivity than the bottom adhesive layer, the intermediate adhesive layer, and the top adhesive layer, while each of the bottom adhesive layer, the intermediate adhesive layer, and the top adhesive layer has a stronger adhesion strength than the bottom conductive layer and the top conductive layer.

20. The method of claim 19 wherein depositing the metal stack comprises:
depositing the bottom adhesive layer directly over the corresponding one of the plurality of metal base sections;
depositing the bottom conductive layer directly over the bottom adhesive layer;
depositing the intermediate adhesive layer directly over the bottom conductive layer;
depositing the top conductive layer directly over the intermediate adhesive layer; and
depositing the top adhesive layer directly over the top conductive layer.

21. The method of claim 20 wherein:
the bottom adhesive layer, the intermediate adhesive layer, and the top adhesive layer are formed of Ti;
the bottom conductive layer is formed Al or Cu; and
the top conductive layer is formed of Al or Cu.

22. The method of claim 21 wherein each of the bottom conductive layer and the top conductive layer has a thickness between 1 μm and 2.5 μm and is formed from one pocket resource.

23. The method of claim 21 wherein:
the bottom adhesive layer has a thickness between 500 Å and 3000 Å;
the intermediate adhesive layer has a thickness between 100 Å and 500 Å;
the top adhesive layer has a thickness between 500 Å and 3000 Å; and
the bottom adhesive layer and the intermediate adhesive layer are deposited at a rate between 1 Å/second and 2 Å/second.

24. The method of claim 19 further comprising forming a patterned dielectric layer over the piezoelectric layer before depositing the metal stack to each of the plurality of metal base sections, wherein:
the patterned dielectric layer covers each of the plurality of reflective structures and each of the plurality of IDTs but leaves each of the plurality of metal base sections exposed; and
the patterned dielectric layer covers portions of the piezoelectric layer that are not covered by the plurality of reflective structures, the plurality of IDTs, and the plurality of metal base sections.
